(19) United States
(12) Patent Application Publication
(10) Pub. No.: US 2025/0202422 A1
(43) Pub. Date: Jun. 19, 2025

(54) COOLING SYSTEM FOR SOLAR ENERGY CONVERSION DEVICE

(71) Applicant: KING FAISAL UNIVERSITY, Al-Ahsa (SA)

(72) Inventors: FATIH SELIMEFENDIGIL, Al-Ahsa (SA); Damla Okulu, Al-Ahsa (SA)

(21) Appl. No.: 18/540,747

(22) Filed: Dec. 14, 2023

(51) Int. Cl. H02S 40/42; H01L 31/048; H02S 40/44; H10N 19/00

(52) U.S. Cl. CPC H02S 40/425; H02S 40/44; H10F 19/804; H10N 19/00

(57) ABSTRACT

A cooling system for a solar energy conversion device is provided. The system includes a photovoltaic panel and a fluid reservoir circulating a nanofluid cooling medium. A primary thermoelectric generator is included on an underside of the photovoltaic panel. A heat pipe is included on an underside of the primary thermoelectric generator. An evaporator portion of the heat pipe is formed by contact with the underside of the photovoltaic panel, while a condenser portion of the heat pipe is immersed in the cooling medium of the fluid reservoir. A secondary thermoelectric generator is included in contact with an underside of the evaporator portion of the heat pipe and a copper heat sink. The photovoltaic panel includes layers of ethylene vinyl acetate and polyvinyl fluoride.

### BACKGROUND

### Field

The disclosure of the present patent application relates to renewable energy sources and cooling systems therefor, and particularly to a cooling system for a solar energy conversion device.

### Description of Related Art

Many regions in the Middle East are ideal locations for the use of solar energy conversion devices, such as photovoltaic panels. The Middle East experiences a high level of solar irradiance due to its geographical location, characterized by clear skies and abundant sunlight throughout the year. As such, solar panels in the region receive ample sunlight, allowing for high energy production and making photovoltaic technology particularly effective, which has led to its rising use throughout the region. In order to maintain efficiency, photovoltaic panels require cooling, as photovoltaic cells are sensitive to temperature and their efficiency decreases as temperatures rise. Most solar panels experience a decrease in efficiency of about 0.5% for every degree Celsius increase in temperature. Prior cooling solutions for photovoltaic panels have included forced air cooling and water cooling. These solutions are particularly disadvantageous, however, due to the energy required from multiple pumps and blowers to distribute the water/air onto the photovoltaic panels. Therefore, a solution is desired for increasing the efficiency of solar conversion devices, while contributing to energy savings at the same time.

### SUMMARY OF THE INVENTION

A cooling system for a solar energy conversion device is provided. The system includes a photovoltaic panel and a fluid reservoir circulating a cooling medium. A primary thermoelectric generator is included on an underside of the photovoltaic panel. A heat pipe is included on an underside of the primary thermoelectric generator. An evaporator portion of the heat pipe is formed by contact with the underside of the photovoltaic panel, while a condenser portion of the heat pipe is immersed in the cooling medium of the fluid reservoir. A secondary thermoelectric generator is included in contact with an underside of the evaporator portion of the heat pipe.

In an embodiment, the cooling system for a solar energy conversion device includes a heat sink, such as a copper heat sink, in contact with an underside of the secondary thermoelectric generator.

In an embodiment, the cooling system for a solar energy conversion device includes a nanofluid as the cooling medium circulating in the fluid reservoir.

In an embodiment, the cooling system for a solar energy conversion device includes one or more layers of ethylene vinyl acetate in the photovoltaic panel.

In an embodiment, the cooling system for a solar energy conversion device includes one or more layers of polyvinyl fluoride in the photovoltaic panel.

These and other features of the present subject matter will become readily apparent upon further review of the following specification.

### BRIEF DESCRIPTION OF DRAWINGS

FIG. 1 is a perspective view of a cooling system for a solar energy conversion device.

FIG. 2A is a side cutaway view of a cooling system for a solar energy conversion device.

FIG. 2B is a side cutaway view of a cooling system for a solar energy conversion device in an expanded state.

Similar reference characters denote corresponding features consistently throughout the attached drawings.

### DETAILED DESCRIPTION

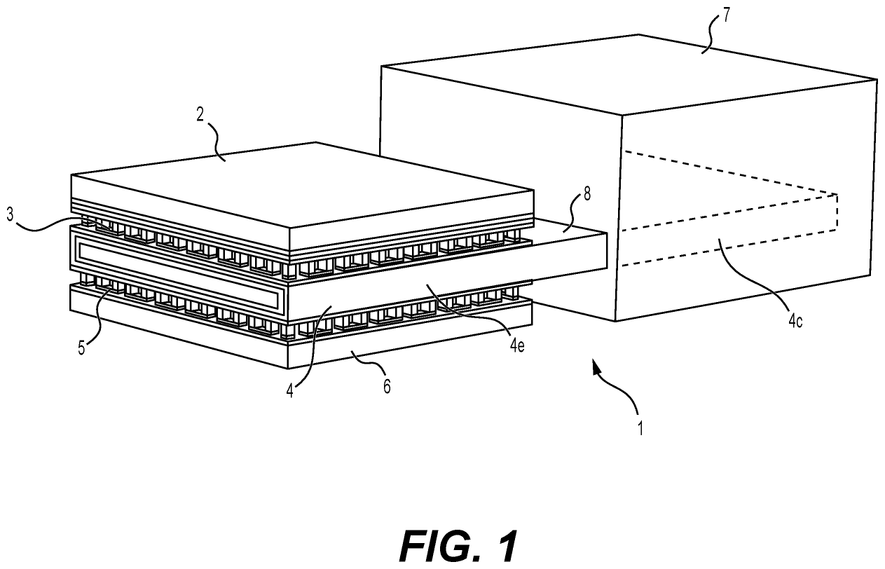

FIG. 1 shows cooling system 1 for a solar energy conversion device, shown as photovoltaic panel 2. System 1 includes a primary thermoelectric generator 3 attached to an underside of photovoltaic (PV) panel 2. Thermoelectric generator 3 and PV panel 2, as well as subsequent layers of system 1 may be joined by any suitable combination of fasteners including but not limited to adhesives, such as thermal adhesives, clamps, magnets, nuts and bolts, welding, and snap-fit connections just to name a few.

On the underside of primary thermoelectric generator 3 is attached a heat pipe 4, whose operation will be explained in greater detail below. On the underside of heat pipe 4 is fastened a secondary thermoelectric generator 5, and on the underside of thermoelectric generator 5 is attached a heat sink 6, such as a copper heat sink. The assembly of photovoltaic panel 2, primary thermoelectric generator 3, secondary thermoelectric generator 5, and heat sink 6 together form an evaporator section 4a of heat pipe 4. A condenser section 4b of heat pipe 4 is formed by a portion of heat pipe 4 that is immersed in a cooling medium within fluid reservoir 7. Heat pipe 4 may be sealed within fluid reservoir 7 by any suitable sealing means such as welding, caulking, gaskets and the like. In a non-limiting embodiment, the cooing medium within fluid reservoir 7 is a nanofluid cooling medium. A nanofluid is a heat transfer fluid with enhanced heat transfer properties created by the addition of nanoparticles. While not a primary focus of the present disclosure, fluid reservoir 7 could be a large central repository for a large solar farm, in which a cooling medium is circulated by a low-powered pump or chiller.

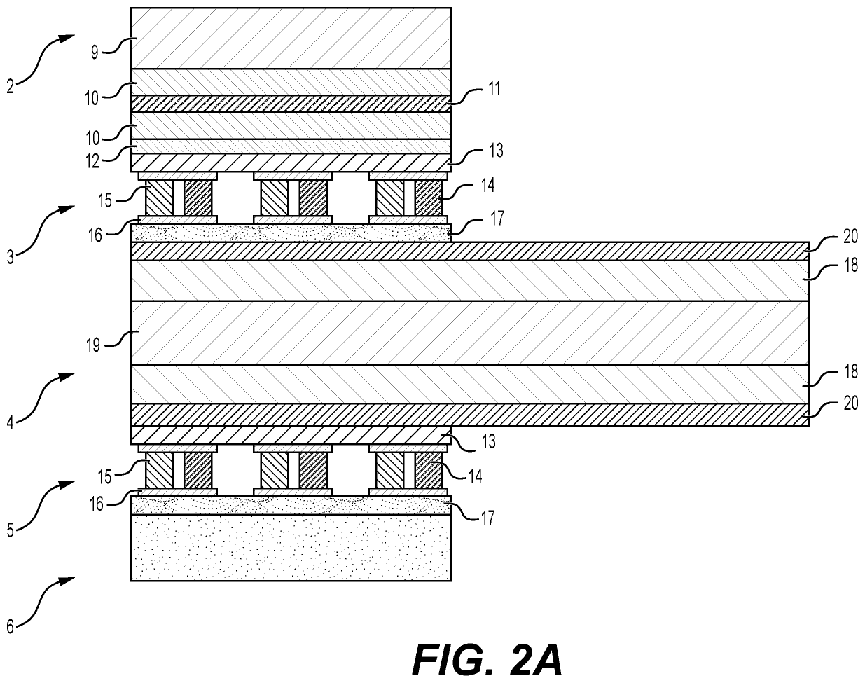

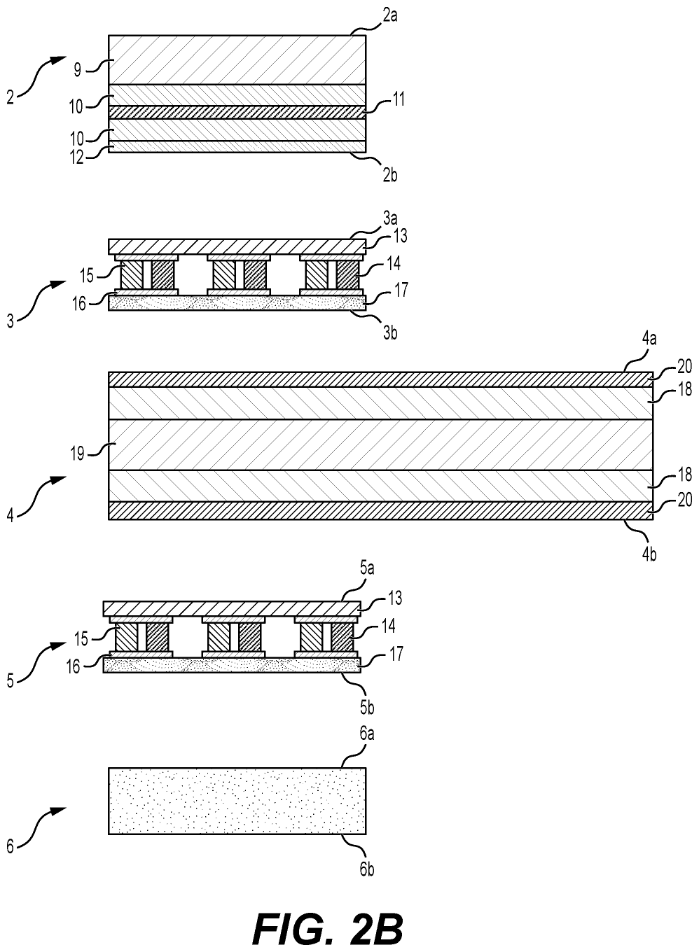

With reference to FIGS. 2A-B the elements of FIG. 1 are shown in greater detail. Photovoltaic (PV) panel 2 includes glass layer 9 forming an uppermost layer and a thermal energy facing side, or sun-facing side 2a. A photovoltaic cell layer 11 is placed between layers of ethylene vinyl acetate 10 for lamination and longevity. A base layer of polyvinyl fluoride 12 is included constituting an underside 2b of PV 2 as a protective layer. Polyvinyl fluoride layer 12 may be for example, a layer of Tedlar™ Polyester Tedlar™ (Tedlar™ is a registered Trademark of DuPont Corporation).

Attached to underside 2b of PV 2 is warm-side ceramic plate 13 of primary thermoelectric generator 3. Warm-side ceramic plate 13 constitutes a warm layer and upper side 3a of thermoelectric generator 3. Following ceramic plate 13 are positive (or P-type) legs 15 and negative (or N-Type) legs 14 between layers of conductor materials 16. P-type legs 15 may be of material such as Bismuth Telluride (Bi₂Te₃), Lead Telluride (PbTe), or Cobalt and Nickel arsenide materials, or skutterudite materials. N-Type legs 15 may formed from Bismuth Antimony Alloys, Lead Telluride dopants, and Half-Heusler alloys such as TiNiSn or ZrNiSn. Underside 3b of primary thermoelectric generator 3 is formed by cool-side ceramic plate 17. In operation, thermoelectric generator 3 generates electricity by the temperature gradient across the thermoelectric legs 15, 16. Due to the Seebeck effect, a voltage is created between the hot and cold sides of the thermoelectric legs 15, 16. This electric current can be used to power electronic devices, charge batteries, or be fed to an electrical grid.

Joined to underside 3b of primary thermoelectric generator 3 is upper side 4a of heat pipe 4. Heat pipe 4 includes tube walls 20, porous wick layers 18, and vapor cavity 19. In operation, a working fluid, such as acetone, moves toward the cold end, i.e. condenser section 4C (FIG. 1), of heat pipe 4 due to the natural pressure gradient within the heat pipe. Wick layers 18 draw the working fluid back to the hot end, i.e. evaporator section 4E (FIG. 1) and in doing so maintain a continuous circulation of the working fluid. While heat pipe 4 may be any shape and size, a flattened shape is particularly desirable due to the added surface area available for efficient bonding to the thermoelectric generators.

Attached to underside 4b of heat pipe 4 is upper side 5a of secondary thermoelectric generator 5. Secondary thermoelectric generator 5 includes warm-side ceramic plate 13 forming upper side 5a joined to heat pipe 4. Cool-side ceramic plate 17 forms underside 5b and is joined to heat sink 6. Although heat sink 6 may be any suitable material, copper is a particularly suitable material due to its high thermal conductivity and corrosion resistance.

The cooling system 1 disclosed herein is advantageous as an efficient cooling solution for solar energy conversion devices. The structure provided allows for natural air circulation of the photovoltaic panel 2, while the addition of a heat pipe 4 provides a self-powered cooling solution which, with the addition of the primary and secondary thermoelectric generators, will contribute to overall energy savings.

It is to be understood that the cooling system for a solar energy conversion device is not limited to the specific embodiments described above, but encompasses any and all embodiments within the scope of the generic language of the following claims enabled by the embodiments described herein, or otherwise shown in the drawings or described above in terms sufficient to enable one of ordinary skill in the art to make and use the claimed subject matter.

1. A cooling system for a solar energy conversion device, comprising:
a photovoltaic panel;
a fluid reservoir circulating a cooling medium;
a primary thermoelectric generator placed on an underside of the photovoltaic panel;
a heat pipe placed on an underside of the primary thermoelectric generator, wherein an evaporator portion of the heat pipe contacts an underside of the photovoltaic panel, and a condenser portion of the heat pipe is immersed in the fluid reservoir, and
a secondary thermoelectric generator contacting an underside of the evaporator portion of the heat pipe.

2. The cooling system for a solar energy conversion device as recited in claim 1, further comprising: a heat sink contacting an underside of the secondary thermoelectric generator.

3. The cooling system for a solar energy conversion device as recited in claim 1, wherein the heat sink is formed of copper.

4. The cooling system for a solar energy conversion device as recited in claim 1, wherein the cooling medium is a nanofluid.

5. The cooling system for a solar energy conversion device as recited in claim 1, wherein the photovoltaic panel comprises one or more layers of ethylene vinyl acetate.

6. The cooling system for a solar energy conversion device as recited in claim 1, wherein the photovoltaic panel comprises one or more layers of polyvinyl fluoride.

7. A cooling system for a solar energy conversion device, comprising:
a photovoltaic panel comprising one or more layers of ethylene vinyl acetate and polyvinyl fluoride;
a fluid reservoir circulating a nanofluid cooling medium;
a primary thermoelectric generator placed on an underside of the photovoltaic panel;
a heat pipe placed on an underside of the primary thermoelectric generator, wherein an evaporator portion of the heat pipe contacts an underside of the photovoltaic panel, and a condenser portion of the heat pipe is immersed in the fluid reservoir;
a secondary thermoelectric generator contacting an underside of the evaporator portion of the heat pipe; and
a copper heat sink placed on an underside of the secondary thermoelectric generator.
